(19) United States
(12) Patent Application Publication
(10) Pub. No.: US 2024/0395877 A1
(43) Pub. Date: Nov. 28, 2024

(54) SHIELDED GATE TRENCH DEVICES HAVING A PLANARIZED THERAMLLY GROWN INTER-POLYSILICON OXIDE STRUCTURE

(71) Applicant: Nami MOS CO., LTD., New Taipei City (TW)

(72) Inventors: FU-YUAN HSIEH, New Taipei City (TW); LIN XU, SHANGHAI (CN)

(73) Assignee: Nami MOS CO., LTD., New Taipei City (TW)

(21) Appl. No.: 18/202,400

(22) Filed: May 26, 2023

(51) Int. Cl. H01L 29/40; H01L 21/265; H01L 29/06; H01L 29/739; H01L 29/78; H01L 29/861

(52) U.S. Cl. CPC H01L 29/407; H01L 21/26513; H01L 21/26586; H01L 29/0634; H01L 29/401; H01L 29/7397; H01L 29/7813; H01L 29/8613

(57) ABSTRACT

Shielded gate devices having a planarized thermally grown (PTG) inter-poly oxide (IPO) structure are disclosed. By using a method having double wet etching processes of a field oxide and double dry etching processes of a first doped polysilicon, the PTG IPO structure is achieved to reduce gate-source leakage current Igss and gate resistance Rg. A gate oxide and a PTG IPO are thermally grown simultaneously. The devices further comprise a current spreading region surrounding a lower portion of a gate electrode for on-resistance reduction.

### FIELD OF THE INVENTION

This invention relates generally to semiconductor devices, and more particularly, to a method for forming a planarized thermally grown (PTG) inter-polysilicon oxide (IPO) in shielded gate trench (SGT) metal oxide semiconductor field effect transistors (MOSFETs). SGT super barrier rectifiers (SBRs), SGT super junction (SJ) MOSFETs and SGT insulating gate bipolar transistors (IGBTs) for gate-source leakage current (Igss) and gate resistance (Rg) reduction. The SGT devices further comprise a current spreading region surrounding a lower portion of a gate electrode below a body region, to achieve a lower on-resistance, smaller gate-drain charge (Qgd) and lower switching loss.

### BACKGROUND OF THE INVENTION

Please refer to FIG. 1 for a conventional SGT MOSFET structure, compared with traditional single gate trench MOSFETs, the SGT MOSFET illustrated in FIG. 1 is more attractive due to a lower gate charge and on-resistance as results of the existence of oxide charge balance (OCB) region in drift region and thick oxide underneath gate electrode. The conventional SGT MOSFET includes a W shape gate electrode 107 above a shielded gate electrode 105 in a gate trench. The shielded gate electrode 105 is insulated from the adjacent epitaxial layer by a field oxide 106, the gate electrode 107 is insulated from the adjacent epitaxial layer by a gate oxide 109, and the gate oxide 109 is surrounding the gate electrode 107 and having a less thickness than the field oxide 106. Moreover, the gate electrode 107 and the shielded gate electrode 105 are insulated from each other by a non-planarized IPO 108, wherein the non-planarized IPO 108 is formed by a single polysilicon etch method to make a W shape gate electrode 107.

The conventional SGT MOSFET has three drawbacks. Firstly, a conventional method for forming the IPO 108 in FIG. 1 is thermally growing the gate oxide and the IPO simultaneously after a single polysilicon etch as shown in FIG. 4C followed by a single field oxide removal from an upper portion of the sidewalls of the gate trench in FIG. 4D. The conventional method makes the shielded gate electrode 105 having a large area overlap with the gate electrode 107, resulting in a high Igss. Secondly, sharp bottom corners of the gate electrode 107 having the thinnest IPO regions to the shielded gate electrode 105 would further make the Igss higher. Thirdly, the shielded gate electrode 105 occupies large amount space in an upper portion of the gate trench, and would lead to a high Rg. A detailed process flow is specified in FIGS. 4A˜4E including the single polysilicon dry etch to form the shielded gate electrode and the single field oxide wet etch to fully remove the field oxide from upper portion of the sidewalls of the gate trenches. The remaining portion of the field oxide in the gate trenches is not coplanar with a top surface of the adjacent shielded gate electrode after the single field oxide wet etch process. The nonplanar structure results in the high Igss due to formation of a large amount area of the IPO and the sharp bottom corners of the gate electrode after the gate oxide and the IPO are thermally grown simultaneously.

Therefore, there is still a need in the art of the semiconductor device design and fabrication, particularly for SGT device design and fabrication, to provide a novel cell structure, device configuration and manufacturing process that making an SGT device have lower specific on-resistance, higher frequency and efficiency applications without having the high Igss and high Rg issues.

### SUMMARY OF THE INVENTION

The present invention discloses a method of fabricating a SGT device in FIG. 2 comprising the following steps. A plurality of gate trenches are formed in an epitaxial layer of a first conductivity type on a substrate. A field oxide is formed on sidewalls and bottoms of the gate trenches. A doped polysilicon layer of the first conductivity type is deposited into the gate trenches. A first polysilicon dry etch is performed to form a shielded gate electrode in lower portions of the gate trenches. A first field oxide wet etch is performed to reduce a thickness of the field oxide on the upper portions of the sidewalls to a desired thickness range. The remaining field oxide is served as a sacrificial layer to protect sidewalls of the gate trenches from damage during a subsequent second polysilicon dry etch process. The second polysilicon dry etch is performed to planarize the shielded gate electrode by removing the top portion of the shielded gate electrode at least above a top surface of the adjacent field oxide. Top surface of the shielded gate electrode is substantially coplanar with the adjacent field oxide after the second polysilicon dry etch process. A second field oxide wet etch is performed to remove the remaining field oxide on the upper portions of the sidewalls of the gate trenches. A gate oxide and an IPO are thermally grown simultaneously on upper portions of sidewalls of the gate trenches and the shielded gate electrodes, respectively. A second doped polysilicon layer of the first conductivity type is deposited and a gate electrode is formed in upper portions of gate trenches after performing a third polysilicon dry etch. The IPO has much less area in the present invention than the conventional method. The method of the present invention having two polysilicon dry etches of the first doped polysilicon and two field oxide wet etches, which is different from the conventional method having one polysilicon dry etch of the first doped polysilicon layer and one field oxide wet oxide etch. A detailed process flow of the present invention is specified in FIGS. 5A˜5E.

According to one aspect, the invention features a SGT device formed in an epitaxial layer of a first conductivity type onto a substrate, further comprising: a plurality of gate trenches surrounded by source regions of the first conductivity type encompassed in body regions of a second conductivity type on a top surface of the epitaxial layer, each of the gate trenches is filled with a gate electrode and a shielded gate electrode, wherein the shielded gate electrode is insulated from the adjacent epitaxial layer by a field oxide, the gate electrode is disposed above the shielded gate electrode and insulated from the adjacent epitaxial layer by a gate oxide, the shielded gate electrode and the gate electrode is insulated from each other by a planarized thermally grown (PTG) Inter-Poly Oxide (IPO), the gate oxide surrounds the gate electrode and has a less thickness than the field oxide; the body regions, the shielded gate electrodes and the source regions are shorted together to a source metal through a plurality of trenched contacts; the present invention also features a SGT device further comprising a current spreading region of the first conductivity type surrounding at least sidewalls of the gate electrodes, wherein the current spreading layer has a higher doping concentration than that of the epitaxial layer. Before formation of the gate oxide, an angle implant of the first conductivity type dopant is performed to form a current spreading region with the first conductivity type surrounding at least a lower portion of the gate electrode below body region with a higher doping concentration than a doping concentration of the epitaxial layer for on-resistance reduction.

According to another aspect, in some preferred embodiments, the epitaxial layer is a single epitaxial layer with an uniform doping concentration. In some other preferred embodiments, the epitaxial layer has multiple stepped epitaxial (MSE) layers comprising at least two stepped epitaxial layers of different doping concentrations decreasing stepwise in a direction from substrate to a top surface of the epitaxial layer, wherein each of the MSE layers has a uniform doping concentration as grown.

According to another aspect, the device further comprises a super junction (SJ) structure comprising a P column region of the second conductivity type disposed above the substrate and connected with the body regions.

According to another aspect, in some preferred embodiments, the substrate has the first conductivity type and the epitaxial layer comprises a single epitaxial layer having an uniform doping concentration. In some other preferred embodiments, the substrate has the second conductivity type and the epitaxial layer comprises a single epitaxial layer having an uniform doping concentration.

According to another aspect, the substrate has the second conductivity type, further comprises a plurality of heavily doped regions of the first conductivity type in the substrate to form a plurality of alternating P+ and N+ regions in the substrate.

According to another aspect, in some preferred embodiment, the substrate has the first conductivity type, an Oxide Charge Balance (OCB) region of the first conductivity is formed in a mesa area between two adjacent gate trenches below the body regions and above a bottom of the shielded gate electrode, a buffer region of the first conductivity type is formed between the substrate and the OCB region, and the epitaxial layer in the OCB region has multiple stepped epitaxial (MSE) layers with different doping concentrations decreasing stepwise in a direction from a bottom of the shielded gate electrode to a top surface of the MSE layers along sidewalls of the gate trenches, wherein each of the MSE layers has an uniform doping concentration as grown. The epitaxial layer in the buffer region has a doping concentration equal to a doping concentration of a bottom epitaxial layer of the MSE layers, or lower than each of the doping concentrations of the MSE layers in the OCB region, or higher than each of the doping concentrations of the MSE layers in the OCB region, or higher than a doping concentration of a top epitaxial layer of the MSE layers in the OCB region but lower than a doping concentration of a bottom epitaxial layer of the MSE layers in the OCB region.

According to another aspect, in some preferred embodiments, the substrate has the first conductivity type and the gate electrode is not electrically shorted together to a source metal, the SGT device is a MOSFET having a gate electrode, a source electrode and a drain electrode.

In some other preferred embodiments, the substrate has the first conductivity type and the gate electrode is electrically shorted together to a source metal; the SGT device is a super barrier rectifier (SBR) having an anode electrode and a cathode electrode, wherein the source region is electrically connected with the anode electrode and the drain region is electrically connected with the cathode electrode.

According to another aspect, in some preferred embodiment, the substrate has the second conductivity type, The epitaxial layer in the buffer region has a doping concentration higher than each of the doping concentrations of the MSE layers in the OCB region.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description to explain the principles of the invention. In the drawings:

FIG. 1 is a cross-sectional view of a conventional SGT MOSFET.

FIG. 2 is a cross-sectional view of a preferred embodiment according to the present invention.

FIG. 3 is a cross-sectional view of another preferred embodiment according to the present invention.

FIGS. 4A-4D are a serial of side cross-sectional views for showing the processing steps for fabricating the SGT MSOFET of FIG. 1.

FIG. 4E is a flow chart including process embodiments for fabricating the SGT MOSFET of FIG. 1.

FIGS. 5A˜5D are a serial of side cross-sectional views for showing the processing steps for fabricating the SGT MSOFET of FIG. 2.

FIG. 5E is a flow chart including process embodiments for fabricating the SGT MSOFET of FIG. 2.

FIGS. 6A-6C are a serial of side cross-sectional views for showing the processing steps for fabricating the SGT MSOFET of FIG. 3.

FIG. 7 is a cross-sectional view of another preferred embodiment according to the present invention, wherein the doping concentration variations of the N type epitaxial layer as grown are depicted along the vertical direction.

FIG. 8A is a cross-sectional view of another preferred embodiment according to the present invention, wherein the doping concentration variations of the N type epitaxial layer as grown are depicted along the vertical direction.

FIG. 8B is a cross-sectional view of another preferred embodiment according to the present invention, wherein the doping concentration variations of the N type epitaxial layer as grown are depicted along the vertical direction.

FIG. 8C is a cross-sectional view of another preferred embodiment according to the present invention, wherein the doping concentration variations of the N type epitaxial layer as grown are depicted along the vertical direction.

FIG. 9 is a cross-sectional view of another preferred embodiment according to the present invention.

FIG. 10 is a cross-sectional view of another preferred embodiment according to the present invention.

FIG. 11 is a cross-sectional view of another preferred embodiment according to the present invention.

FIG. 12 is a cross-sectional view of another preferred embodiment according to the present invention.

FIG. 13 is a cross-sectional view of another preferred embodiment according to the present invention.

FIG. 14 is a cross-sectional view of another preferred embodiment according to the present invention, wherein the doping concentration variations of the N type epitaxial layer as grown are depicted along the vertical direction.

FIG. 15A is a cross-sectional view of another preferred embodiment according to the present invention, wherein the doping concentration variations of the N type epitaxial layer as grown are depicted along the vertical direction.

FIG. 15B is a cross-sectional view of another preferred embodiment according to the present invention, wherein the doping concentration variations of the N type epitaxial layer as grown are depicted along the vertical direction.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

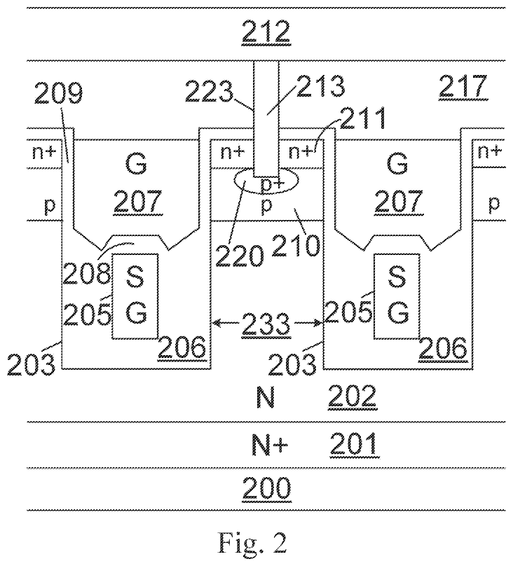

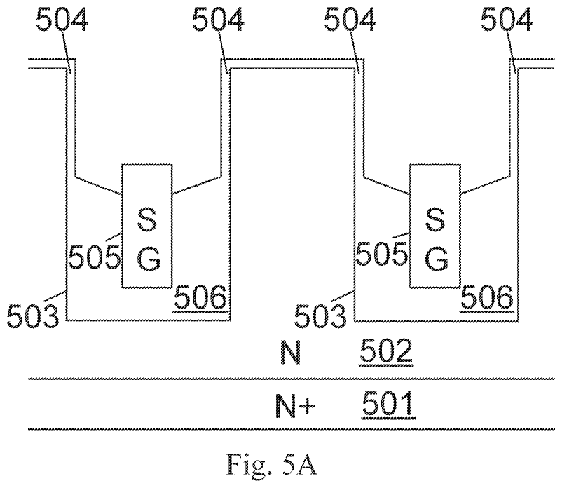

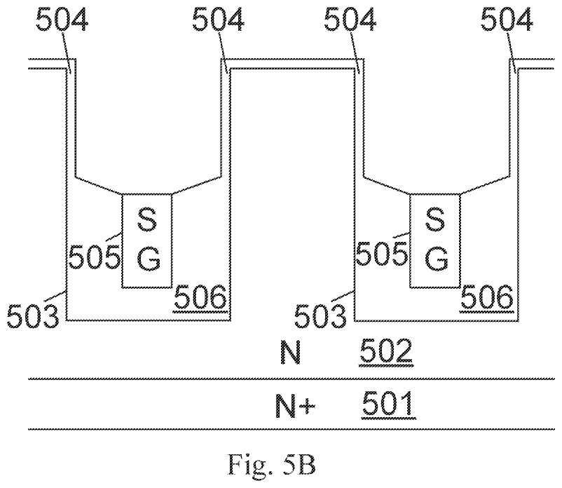

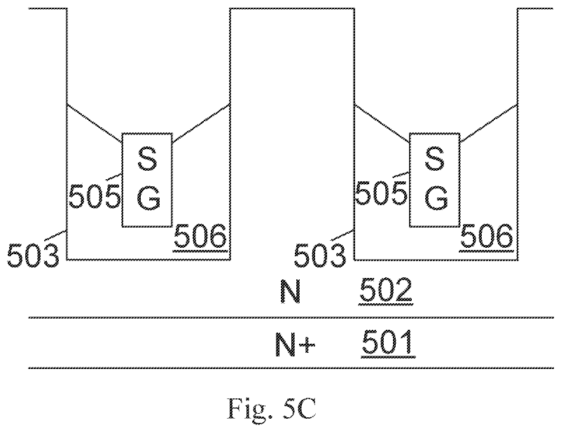

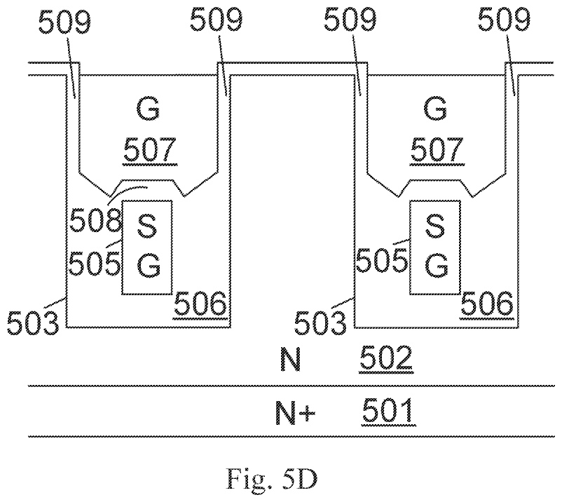

Please refer to FIG. 2 for a preferred embodiment of this invention with new and improved device structure, wherein an N-channel SGT MOSFET is formed in an N type epitaxial layer 202 on an N+ substrate 201 as a drain region coated with a back metal 200 of Ti/Ni/Ag on rear side as a drain metal. Inside the N epitaxial layer 202, a plurality of gate trenches 203 are formed vertically downward from a top surface of the N type epitaxial layer 202 and not reaching the common interface between the N type epitaxial layer 202 and the N+ substrate 201. Inside each of the gate trenches 203, a shielded gate electrode (SG, as illustrated) 205 is disposed in the lower portion and a single U shape gate electrode (G, as illustrated) 207 is disposed in the upper portion. The shielded gate electrode 205 is insulated from the adjacent epitaxial layer by a first insulating film 206 as a field plate oxide, and the gate electrode 207 is insulated from the adjacent epitaxial layer by a gate oxide 209, wherein the gate oxide 209 has a thinner thickness than the field oxide 206 which has an uniform thickness along trench sidewalls, meanwhile, the shielded gate electrode 205 and the gate electrode 207 is insulated from each other by a second insulating film 208 as an planarized IPO. Moreover, the planarized IPO is formed by the double polysilicon dry etch method specified in the FIGS. 5A-5E making a U shape gate electrode 207. Between every two adjacent gate trenches 203, the P body regions 210 with n+ source regions 211 thereon are extending at top portion of the N epitaxial layer 202, wherein top surface of the shielded gate electrode 207 is below the P body regions 210. The P body regions 210, the shielded gate electrodes 205 and the n+ source regions 211 are further shorted together to a source metal 212 through a plurality of trenched contacts 223 filled with metal contact plugs and metal barriers 213 implemented by penetrating through a contact insulating layer 217 and surrounded by p+ heavily doped regions 220 around bottoms underneath the n+ source regions 211. According to the invention, an OCB region is therefore formed in a mesa area 233 between the two adjacent gate trenches 203.

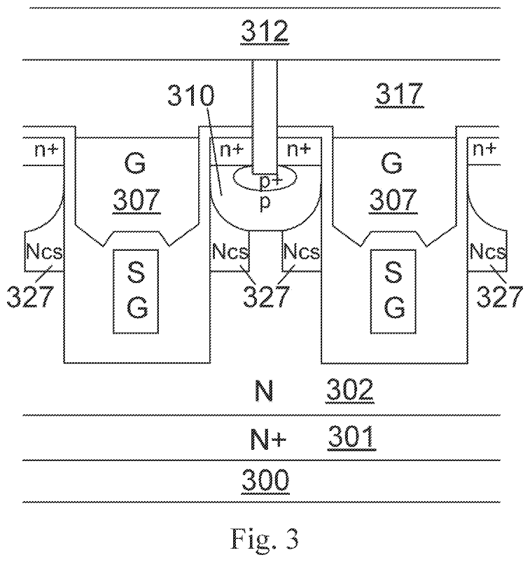

Please refer to FIG. 3 for another preferred embodiment of this invention with new and improved device structure. The SGT device has a similar structure to FIG. 2, except that in the present structure, a current spreading region 327 of the first conductivity type (Ncs, as illustrated) is encompassed in upper portion of the epitaxial layer 302 and below the p body regions 310 and surrounds at least sidewalls of the gate electrode 307. The Ncs region 327 is introduced by angle trench sidewall implant of the first conductivity type dopant, and a doping concentration of the Nos region is higher than that of the epitaxial layer 302 for on-resistance reduction.

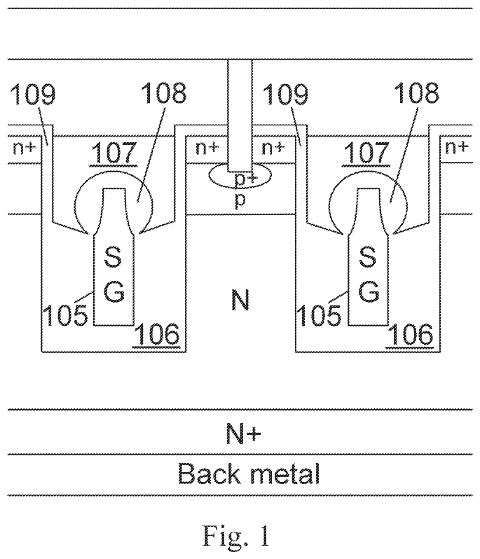

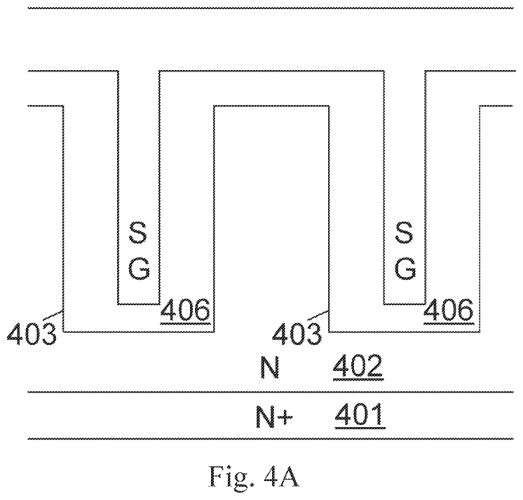

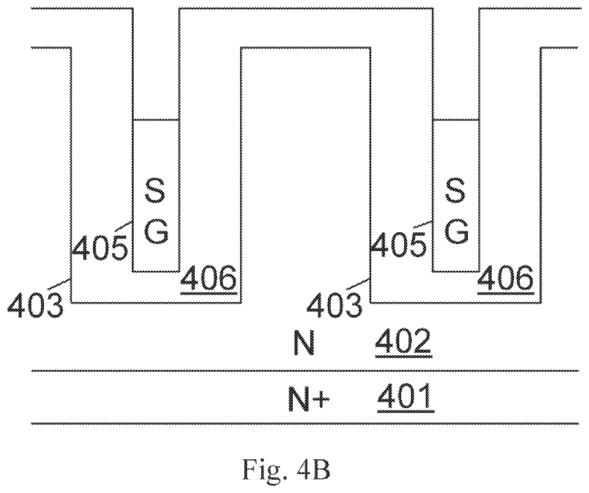

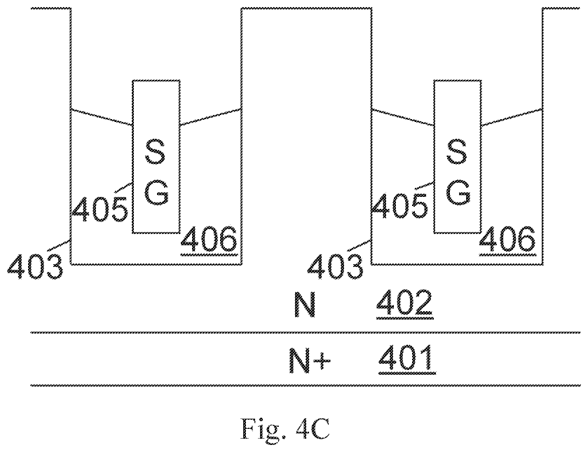

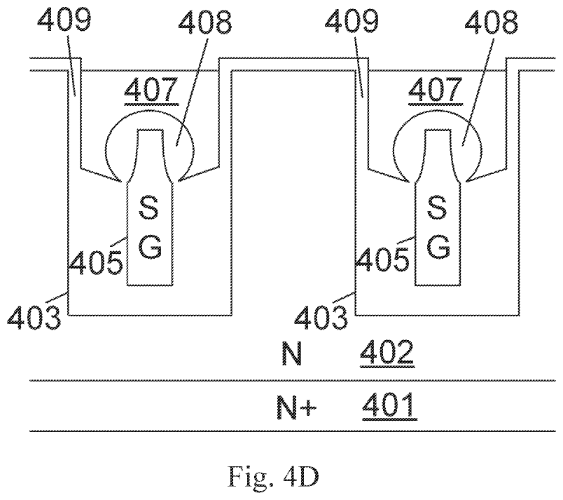

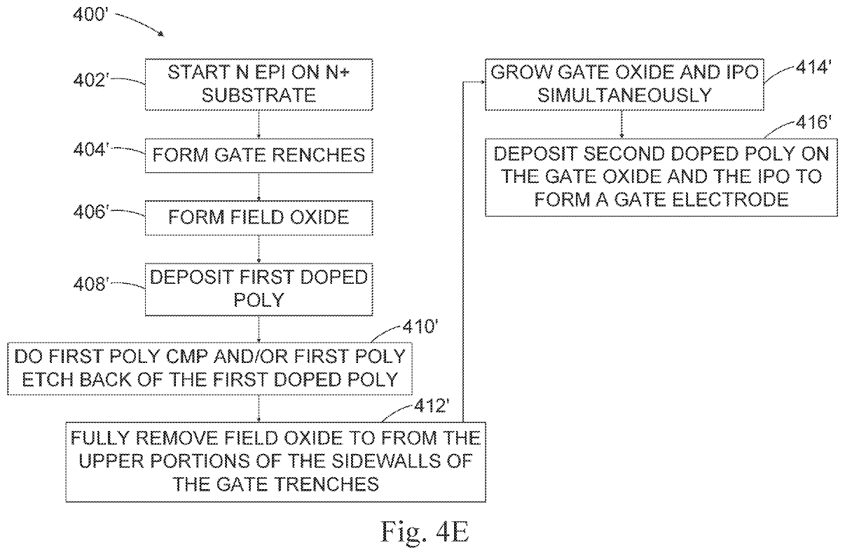

FIGS. 4A˜4D are a serial of exemplary steps that are performed to fabricate the SGT MSOFET of FIG. 1. In FIG. 4A, an N epitaxial layer 402 is grown on an N+ substrate 401, a hard mask (not shown) such as an oxide layer is applied onto a top surface of the N epitaxial layer 402 for definition of areas for a plurality of gate trenches. Then, after dry oxide etch and dry silicon etch, a plurality of gate trenches 403 are etched penetrating through open regions in the hard mask and down into the N epitaxial layer 402, not reaching the bottom surface of N epitaxial layer 402. Mesas are thus formed between every two adjacent gate trenches 403 in the N epitaxial layer 402. Then, a sacrificial oxide layer (not shown) is first grown and then removed to eliminate the plasma damage after forming the gate trenches 403. The hard mask is removed, and a thick field oxide 406 is formed lining the inner surface of the gate trenches 403 by thermal oxide growth and/or thick oxide deposition. Then, a first doped poly-silicon layer is deposited onto the first gate insulation layer 406 to fill the gate trenches 403.

In FIG. 4B, a first polysilicon CMP (chemical and mechanical ploish) and/or a first polisicon dry etch process are performed to form shielded gate electrodes 405 in lower potions of the gate trenches 403.

In FIG. 4C, the field oxide 406 is removed from top surface of the epitaxial layer and from upper portions of the gate trenches 403.

In FIG. 4D, a gate oxide 409 on the upper inner surfaces of the gate trenches 403 and a non-planarized IPO 408 on the shielded gate electrode 405 are simultaneously grown. Then a second doped polysilicon layer is deposited on the gate oxide 409 and the IPO 408, and a second polysilicon CMP and/or a second polysilicon dry etch processes are performed to form the W shape gate electrodes 407 in upper portions of the gate trenches 403.

Flow chart in FIG. 4E shows an exemplary process flow embodiment 400′ of the SGT MOSFET of FIG. 1. Referring to FIG. 4E, and collectively to the figures, in one embodiment, in step 402′, starting wafer may include an epitaxial layer (n epi layer) grown on an n+ silicon substrate. In step 404′, gate trenches are formed in the epitaxial layer. In step 406′, a field oxide may be preferably be formed on trench sidewalls and bottom walls of the gate trenches. In step 408′, a first doped polysilicon layer is deposited within the gate trenches which is entirely coated with the field oxide layer formed in step 406′. In step 410′, the first poly CMP and/or first poly dry etch processes are applied to the first doped polysilicon layer for formation of the shielded gate electrodes. In step 412′, the field oxide layer formed in step 406′ is removed from top surface of the epitaxial layer and an upper portion of the gate trenches. In step 414′, a gate oxide layer and an IPO are grown simultaneously. In step 416′, a second doped polysilicon layer is deposited on the gate oxide and the IPO to form a gate electrode.

FIGS. 5A˜5D are a serial of exemplary steps that are performed to fabricate the SGT MSOFET of FIG. 2. In FIG. 5A, an N epitaxial layer 502 is grown on an N+ substrate 501, a hard mask (not shown) such as an oxide layer is applied onto a top surface of the N epitaxial layer 502 for definition of areas for a plurality of gate trenches. Then, after dry oxide etch and dry silicon etch, a plurality of gate trenches 503 are etched penetrating through open regions in the hard mask and down into the N epitaxial layer 502, not reaching the bottom surface of N epitaxial layer 502. Mesas are thus formed between every two adjacent gate trenches 503 in the N epitaxial layer 502. Then, a sacrificial oxide layer (not shown) is first grown and then removed to eliminate the plasma damage after forming the gate trenches 503. The hard mask is removed, and a thick field oxide layer is formed lining the inner surface of the gate trenches 503 by thermal oxide growth and/or thick oxide deposition. Then, a first doped poly-silicon layer is deposited onto the field oxide 506 to fill the gate trenches 503. A first polysilicon CMP (chemical and mechanical ploish) and/or a first polisicon dry etch process are performed to form shielded gate electrodes 505 in lower potions of the gate trenches 503.

In FIG. 5A, a thickness of the field oxide 506 on upper portions of the sidewalls of the gate trenches is then reduced to a desired thickness range by a first wet oxide etch. The remaining field oxide 504 with a desired thickness range of 10%-30% of the field oxide is served as a sacrificial layer to protect the sidewalls from damage during a subsequent second poly silicon etch process.

In FIG. 5B, a second poly silicon etch is performed to make a top surface of the shielded electrode 505 align to a top surface of the adjacent field oxide by removing a top portion of said shielded gate electrode that is at least higher than a top surface of said adjacent field oxide;

In FIG. 5C, the remaining field oxide 506 on the upper portions of the sidewalls of the gate trenches 503 is removed.

In FIG. 5D, a gate oxide 509 on the upper portions of the sidewalls of the gate trenches 503 and an PTG IPO 508 on top surface of the shielded gate electrode 505 are thermally grown simultaneously. Then, a second doped polysilicon is deposited and a second polysilicon CMP and/or a third polysilicon dry etch are performed to form a gate electrode 507 on the gate oxide 509 and the PTG IPO 508.

Flow chart in FIG. 5E shows an exemplary process flow embodiment 500′ of the SGT MOSFET of FIG. 2. Referring to FIG. 5E, and collectively to the figures, in one embodiment, in step 502′, starting wafer may include an epitaxial layer (n epi layer) grown on an n+ silicon substrate. In step 504′, gate trenches and are formed in the epitaxial layer. In step 506′, a field oxide is formed on trench sidewalls and bottom walls of the gate trenches. The field oxide may be preferably be grown on the silicon sidewalls and bottom walls. In step 508′, a first doped polysilicon layer is deposited within the gate trenches which is entirely coated with the field oxide layer formed in step 506′. In step 510′, the first poly CMP and/or first poly dry etch processes are applied to the first doped polysilicon layer for formation of the shielded gate electrodes. In step 512′, a thickness of the field oxide on upper portions of sidewalls of the gate trenches formed in step 506′ may be etched down to a desired thickness range. In step 514′, a second polysilicon etch is performed to the first doped polysilicon layer for planarization of the shielded gate electrode by removing a portion of the shielded gate electrode at least above top surface of the adjacent field oxide. In step 516′, the remaining field oxide having the desired thickness range from the upper portions of the sidewalls of the gate trenches is removed. In step 518′, a gate oxide on the upper portions of the sidewalls of the gate trenches and a PTG IPO on the top surface of the shielded gate electrode are grown simultaneously. In step 520′, a second doped polysilicon is deposited on the gate oxide and a second polysilicon CMP and/or a third polysilicon dry etch are performed to form a gate electrode.

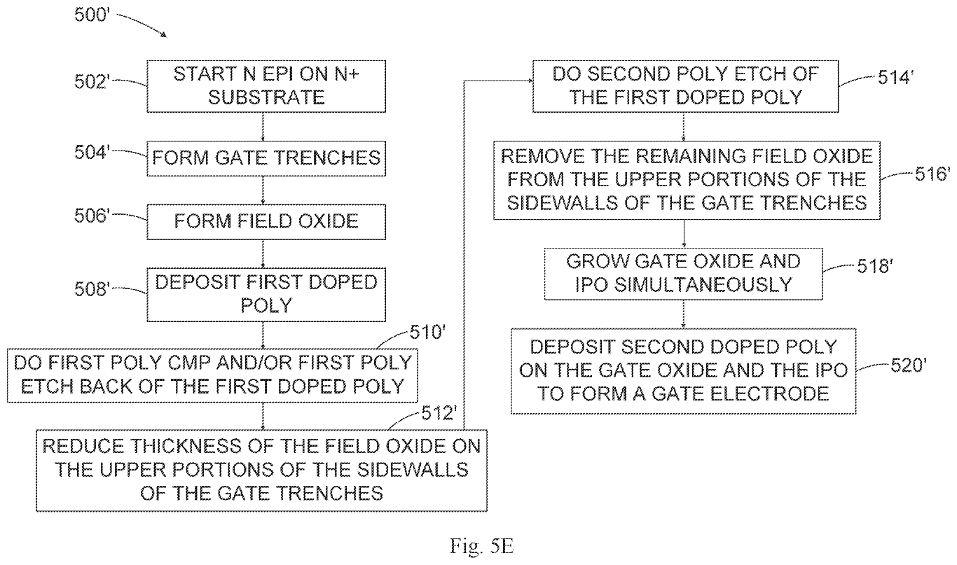

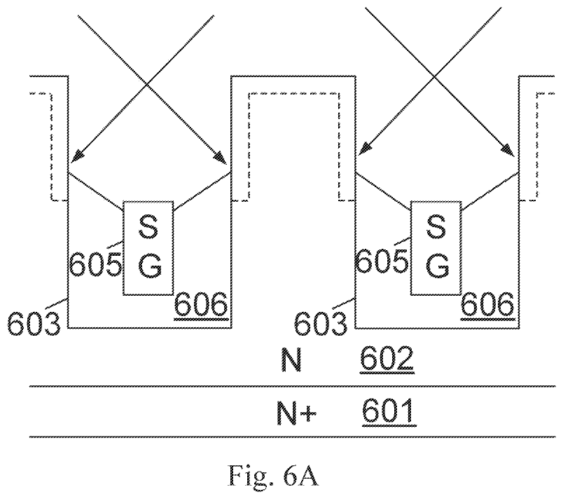

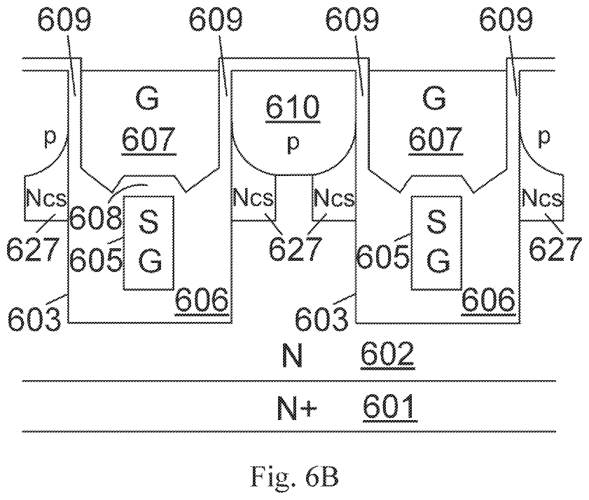

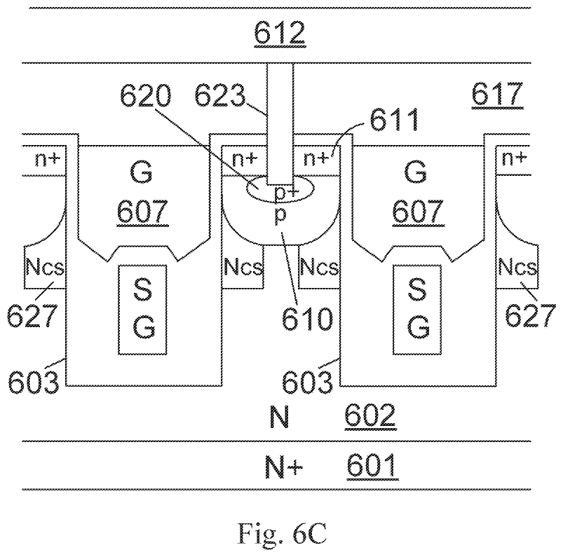

FIGS. 6A˜6C are a serial of exemplary steps that are performed to fabricate the SGT MSOFET of FIG. 3. In FIG. 6A, after the remaining field oxide on the upper portions of the sidewalls of the gate trenches 603 is removed and before formation of the gate oxide, an angle implant of the first conductivity type dopant is performed to form a current spreading region 627 of the first conductivity in FIG. 6B with a doping concentration higher than a doping concentration of the epitaxial layer 602.

In FIG. 6B, a gate oxide 609 on the upper portions of the sidewalls of the gate trenches 603 and an PTG IPO 608 on top surface of the shielded gate electrode 605 are thermally grown simultaneously. Then, a second doped polysilicon is deposited and a second polysilicon CMP and/or a second polysilicon etch processes are performed to form a gate electrode 607 on the gate oxide 609 and the PTG IPO 608. Then, a body implantation of p conductivity type dopant followed by diffusion process is carried out over to form p body regions 610 between every two adjacent gate trenches 603.

In FIG. 6C, after applying a source mask (not shown) onto the top surface of the epitaxial layer 602, a source implantation of n conductivity type dopant and a diffusion step are successively carried out to form an n+ source region 611 near a top surface of the p body regions 610 between two adjacent gate trenches 603. Another oxide layer is deposited onto the top surface of the epitaxial layer 602 to serve as a contact interlayer 617. Then, after applying a contact mask (not shown) onto the contact interlayer 617, a plurality of trenched contacts 623 are formed by successively dry oxide etch and dry silicon etch penetrating through the contact interlayer 617, and extending into the p body regions 610 for trenched source-body contacts. Next, a BF2 Ion Implantation is performed to form a p+ body contact doped region 620 within the p body regions 610 and surrounding at least bottom of the trenched source body-contacts penetrating through the n+ source region 611. A barrier metal layer of Ti/TIN or Co/TiN or Ta/TiN is deposited on sidewalls and bottoms of all the trenched contacts followed by a step of rapid thermal anneal (RTA) process for silicide formation. Then, a tungsten material layer is deposited onto the barrier layer, wherein the tungsten material layer and the barrier layer are then etched back to form contact metal plug for the trenched source-body contacts 623. Then, a metal layer of Al alloys or Cu padded by a resistance-reduction layer Ti or Ti/TiN underneath is deposited onto the contact interlayer 617 and followed by a metal etching process by employing a metal mask (not shown) to be patterned as a source metal 612.

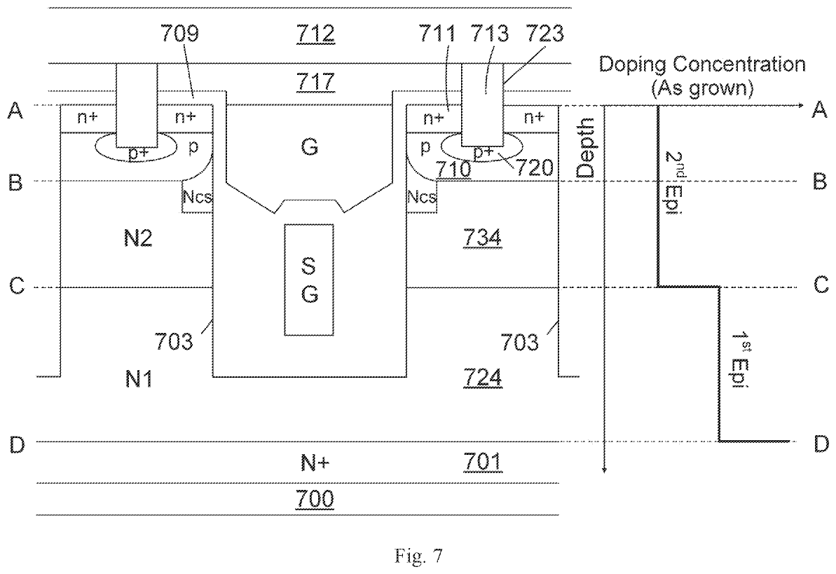

Please refer to FIG. 7 for another preferred embodiment of the present invention, wherein the doping concentration variations of the N type epitaxial vial layer as grown are depicted along the vertical direction. The SGT device has a similar structure to FIG. 3, except for the different epitaxial layers. In this invention, the N type epitaxial layer comprises two stepped epitaxial layers of different doping concentrations including a bottom first epitaxial layer (N1, as illustrated) 724 with a doping concentration D1 and a top second epitaxial layer (N2, as illustrated) 734 above the bottom first epitaxial layer 724 with a doping concentration D2, wherein D2<D1, to increase the breakdown voltage and lower the specific on-resistance.

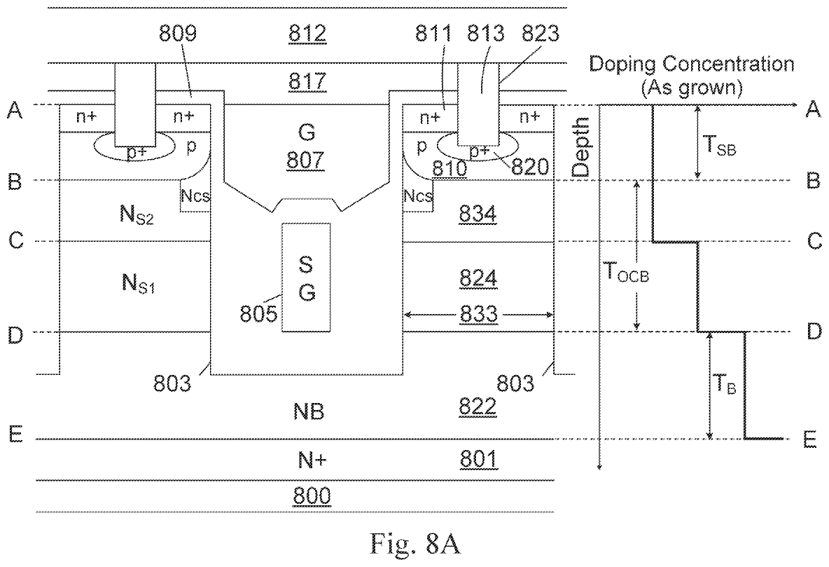

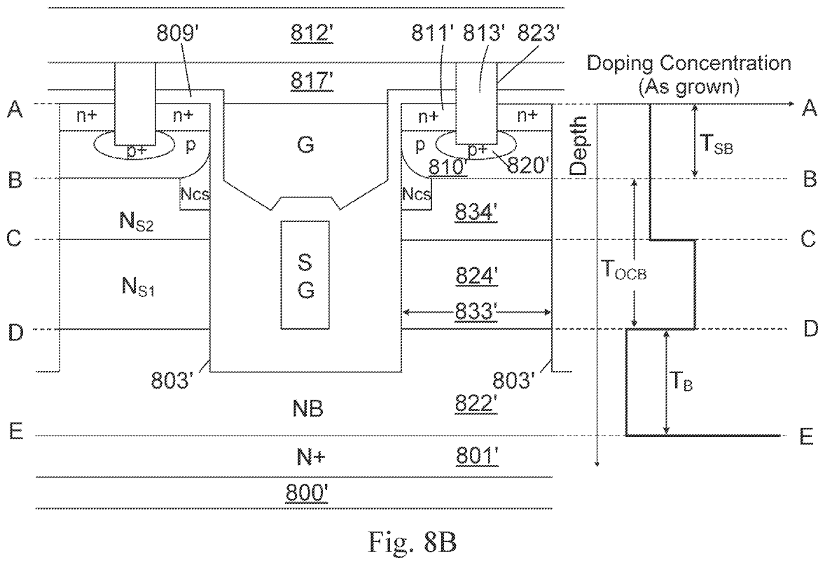

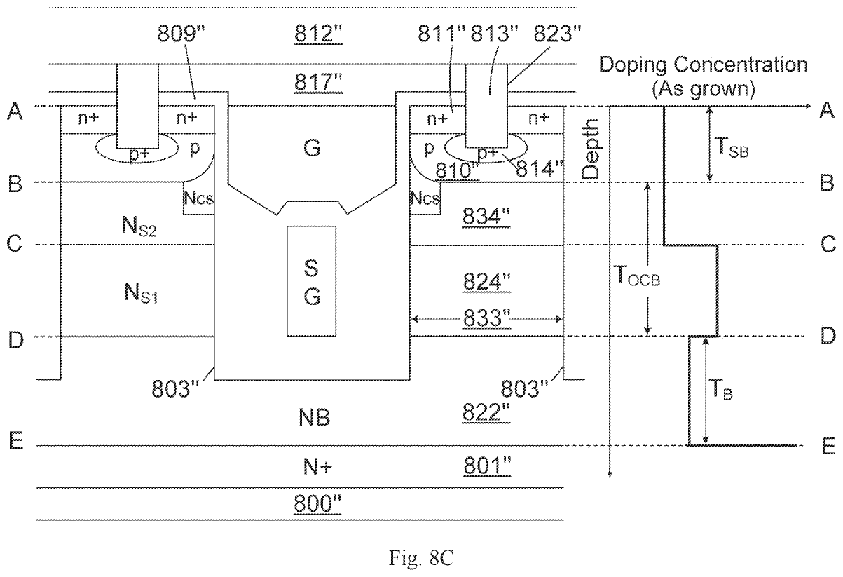

Please refer to FIG. 8A for another preferred embodiment of the present invention, wherein the doping concentration variations of the N type epitaxial layer as grown are depicted along the vertical direction. The SGT device has a similar structure to FIG. 3, except for the different epitaxial layers. In FIG. 8A, the epitaxial layer comprises a source-body (SB) region T_{SB} (between A-A and B-B lines) on a top portion of the epitaxial layer, an OCB region T_{OCB} (between B-B and D-D lines) formed in a mesa area 833 between the two adjacent gate trenches 803 below the body regions 810 and above a bottom of the shielded gate electrode 807 and a buffer region T_{B} (between D-D and E-E lines) formed between the N+ substrate 801 and a bottom of the shielded gate electrode 805, the epitaxial layer in the OCB region has two stepped epitaxial layers with different doping concentrations including a bottom first epitaxial layer (N_{S1}, as illustrated between C-C and D-D lines) 824 above the buffer epitaxial layer (N_{B}, as illustrated between D-D and E-E lines) 822 with a doping concentration D1, and a top second epitaxial layer (N_{S2}, as illustrated between B-B and C-C lines) 834 above the first epitaxial layer 824 with a doping concentration D2, wherein D2<D1. Moreover, the epitaxial layer in the source regions and body regions T_{SB} has a doping concentration same as that of the top second epitaxial layer 834 of the MSE layers in the OCB region T_{OCB}, and the buffer epitaxial layer 822 has a doping concentration DB higher than doping concentrations of the MSE layers in the OCB region T_{OCB}.

Please refer to FIG. 8B for another preferred embodiment of the present invention, wherein the doping concentration variations of the N type epitaxial layer as grown are depicted along the vertical direction. The SGT device has a similar structure to FIG. 8A, except for the different doping concentration of the buffer region T_{B}. In FIG. 8B, the epitaxial layer in the buffer region (N_{B}, as illustrated between D-D and E-E lines) 822′ has a doping concentration DB lower than that of each of the MSE layers in the OCB region T_{OCB}.

Please refer to FIG. 8C for another preferred embodiment of the present invention, wherein the doping concentration variations of the N type epitaxial layer as grown are depicted along the vertical direction. The SGT device has a similar structure to FIG. 8B, except for the different doping concentration of the buffer region T_{B}. In FIG. 8C, the epitaxial layer in the buffer region (NB, as illustrated between D-D and E-E lines) 822″ has a doping concentration DB lower than a doping concentration D1 of a bottom first epitaxial layer (N_{S1}, as illustrated between C-C and D-D lines) 824″ in the OCB region T_{OCB} but higher than a doping concentration D2 of a top second epitaxial layer (N_{S2}, as illustrated between B-B and C-C lines) 834″ in the OCB region T_{OCB}.

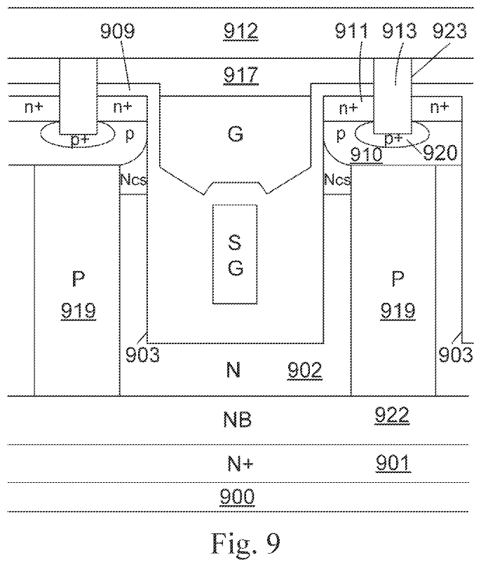

Please refer to FIG. 9 for another preferred embodiment of the present invention. The SGT device has a similar structure to FIG. 3, except that in FIG. 9, the invention further comprises a N buffer layer (NB, as illustrated) 922 with a resistivity Rb sandwiched between the N+ substrate 901 and the N epitaxial layer 902, the N epitaxial layer 902 comprises a single epitaxial layer having an uniform doping concentration with a resistivity R, wherein the R<the Rb. Besides, P column regions 919 are introduced into the N epitaxial layer 902 to form a SJ region, comprising a plurality of alternating P column regions 919 and N regions 902. The P column regions 919 are formed below the p body regions 910 and touch to the bottom surface of the N epitaxial layer 902 by multiple epi method or by opening a deep trench filled up with an epitaxial layer of the second conductivity type method.

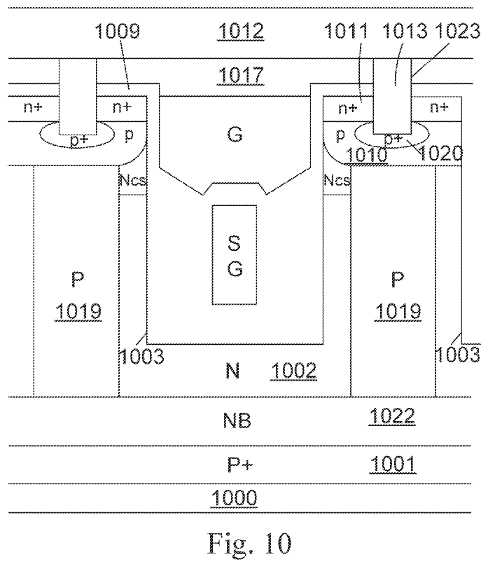

Please refer to FIG. 10 for another preferred embodiment of the present invention. The N-channel SGT device representing an Insulating Gate Bipolar Transistor (IGBT) device has a similar structure to FIG. 9, except for the different substrate and the R>the Rn. In this invention, the IGBT is formed onto a P+ substrate 901.

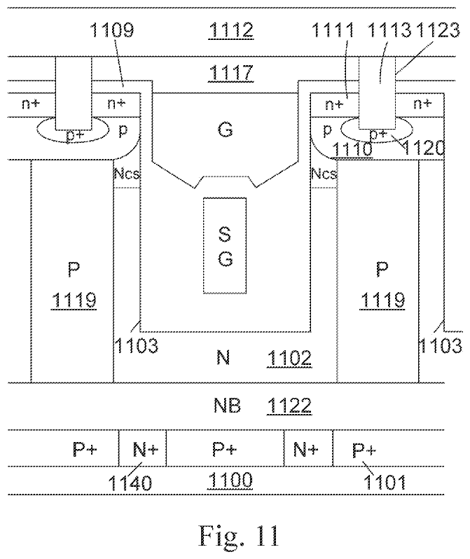

Please refer to FIG. 11 for another preferred embodiment of the present invention. The N-channel SGT device has a similar structure to FIG. 10, except that, the IGBT in FIG. 11 further comprises a plurality of heavily doped N+ regions 1140 formed in the P+ substrate 1101 to form a plurality of alternating P+ and N+ regions in the substrate.

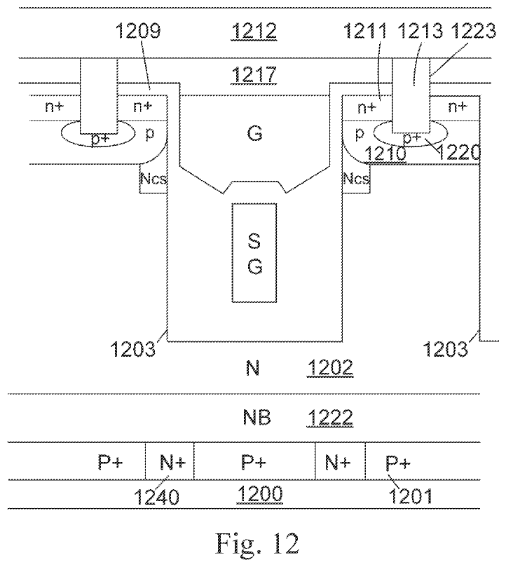

Please refer to FIG. 12 for another preferred embodiment of the present invention. The N-channel SGT device representing an IGBT device has a similar structure to FIG. 3, except that, the IGBT in FIG. 12 further comprises an additional buffer layer 1222 sandwiched between the P+ substrate 1201 and the N epitaxial layer 1202, and a plurality of heavily doped N+ regions 1240 formed in the P+ substrate 1201 to form a plurality of alternating P+ and N+ regions in the substrate.

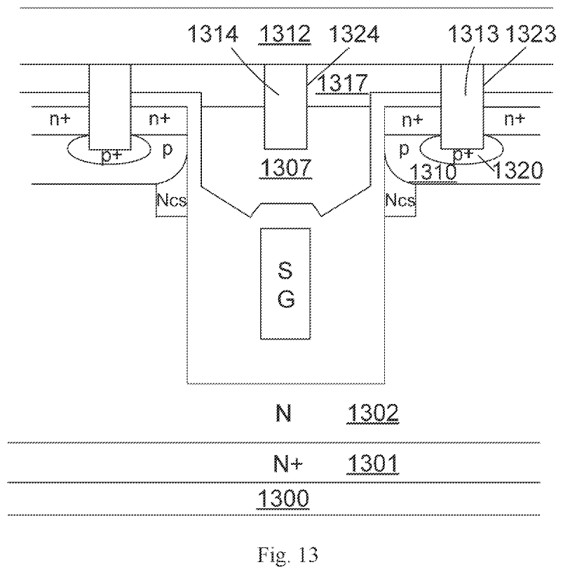

Please refer to FIG. 13 for another preferred embodiment of the present invention with single epitaxial layer. The N-channel SGT SBR device has a similar device structure to FIG. 3, except that, in this invention, the gate electrodes 1307 are electrically shorted together to a source metal 1312 by a plurality of trenched contacts 1324 filled with metal contact plugs and metal barriers 1314, which are implemented by penetrating through a contact insulating layer 1317 and extending into the gate electrodes 1307. The device has the source metal 1312 as anode electrode and a back metal 1300 as cathode electrode.

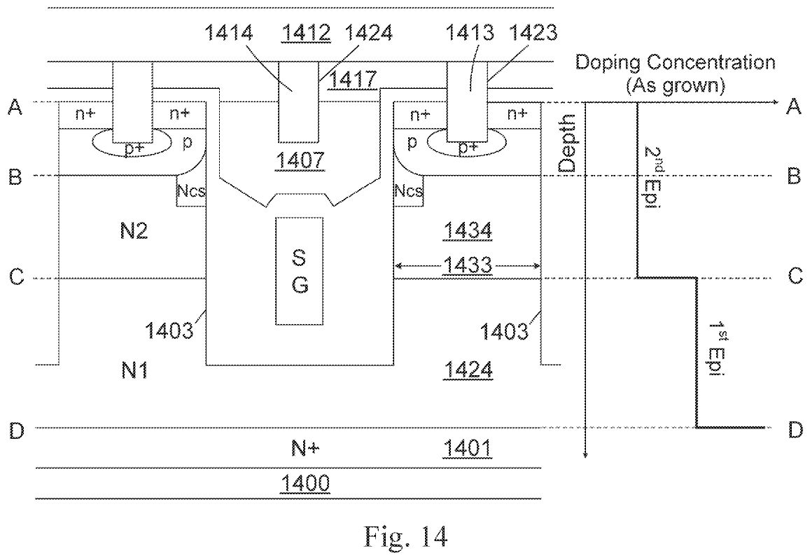

Please refer to FIG. 14 for another preferred embodiment of the present invention, wherein the doping concentration variations of the N type epitaxial layer as grown are depicted along the vertical direction. The SGT SBR device has a similar structure to FIG. 7, except that, in this invention, the gate electrodes 1407 are electrically shorted together to a source metal 1412 by a plurality of trenched contacts 1424 filled with metal contact plugs and metal barriers 1414, which are implemented by penetrating through a contact insulating layer 1417 and extending into the gate electrodes 1407. The device has the source metal 1412 as anode electrode and a back metal 1400 as cathode electrode.

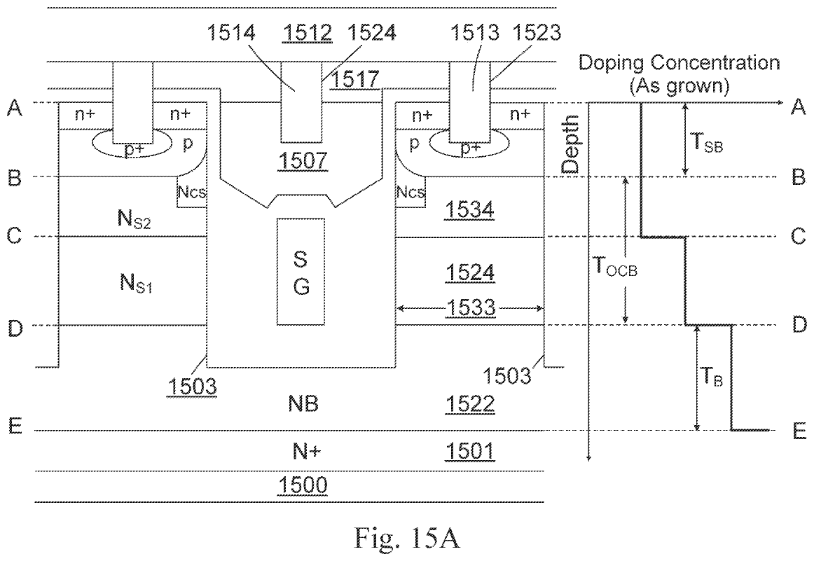

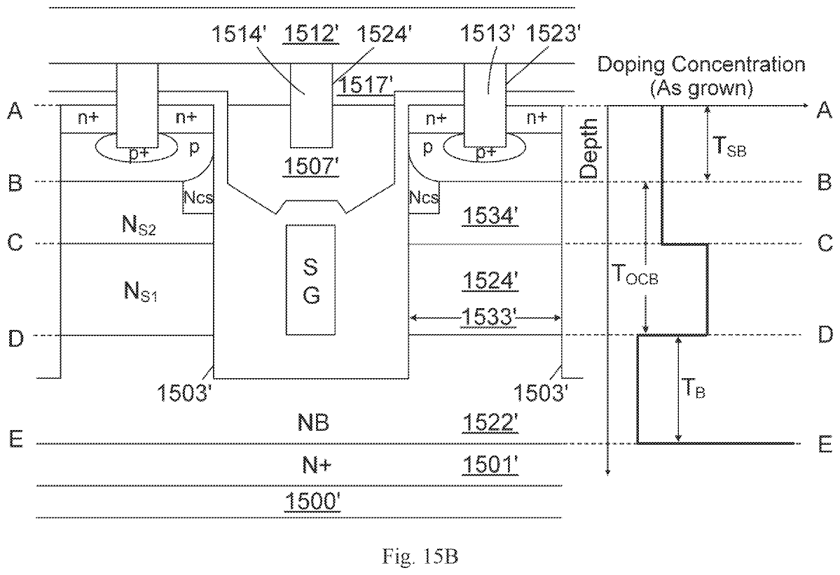

Please refer to FIG. 15A for another preferred embodiment of the present invention, wherein the doping concentration variations of the N type epitaxial layer as grown are depicted along the vertical direction. The SGT SBR device has a similar structure to FIG. 8A, except that, in this invention, the gate electrodes 1507 are electrically shorted together to a source metal 1512 by a plurality of trenched contacts 1524 filled with metal contact plugs and metal barriers 1514, which are implemented by penetrating through a contact insulating layer 1517 and extending into the gate electrodes 1507. The device has the source metal 1512 as anode electrode and a back metal 1500 as cathode electrode.

Please refer to FIG. 15B for another preferred embodiment of the present invention, wherein the doping concentration variations of the N type epitaxial layer as grown are depicted along the vertical direction. The SGT SBR device has a similar structure to FIG. 8B, except that, in this invention, the gate electrodes 1507′ are electrically shorted together to a source metal 1512′ by a plurality of trenched contacts 1524′ filled with metal contact plugs and metal barriers 1514′, which are implemented by penetrating through a contact insulating layer 1517′ and extending into the gate electrodes 1507′. The device has the source metal 1512′ as anode electrode and a back metal 1500′ as cathode electrode.

For all the described preferred embodiment, the first type conductivity type is N type and the second conductivity type is P type, the opposite is also applicable to the present invention when the first type is P type and the first type is N type.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A method for manufacturing shielded gate trench (SGT) devices, comprising:
forming a plurality of gate trenches in a semiconductor of a first conductivity type;
forming a field oxide by thermal oxide growth and/or an oxide deposition on sidewalls and bottoms of said gate trenches;
depositing a first doped polysilicon layer of said first conductivity type;
performing a first polysilicon chemical and mechanical polish (CMP) and/or a first polysilicon dry etch of said first doped polysilicon layer to form shielded gate electrodes in lower potions of said gate trenches;
reducing a thickness of said field oxide on upper portions of sidewalls of said gate trenches to a desired thickness range by a first wet oxide etch;
performing a second polysilicon dry etch of said first doped polysilicon layer for planarization of said shielded gate electrode by removing a top portion of said shielded gate electrode;
removing said remaining field oxide having said desired thickness range from said upper portions of said sidewalls of said gate trenches by a second wet oxide etch;
thermally growing a gate oxide on said upper portions of said sidewalls of said gate trenches and forming a planarized thermally grown (PTG) inter-polysilicon oxide (IPO) on said top surface of said shielded gate electrode simultaneously; and
depositing a second doped polysilicon layer of said first conductivity type to form a gate electrode over said PTG IPO in said upper portions of said gate trenches.

2. The method of claim 1, wherein said second polysilicon dry etch removes a top portion of said shield gate electrode that is at least higher than a top surface of said adjacent field oxide.

3. The method of claim 1, before formation of said gate oxide, an angle implant of said first conductivity type dopant is performed to form a current spreading region of said first conductivity surrounding at least a lower portion of said gate electrode with a doping concentration higher than a doping concentration of said epitaxial layer.

4. A SGT device formed in an epitaxial layer of a first conductivity type on a substrate coated with a back metal, further comprising:
a plurality of gate trenches surrounded by source regions of said first conductivity type being encompassed in body regions of a second conductivity type, each of said gate trenches being filled with a gate electrode and a shielded gate electrode; said shielded gate electrode being insulated from said epitaxial layer by a field oxide, said gate electrode being insulated from said epitaxial layer by a gate oxide, said shielded gate electrode and said gate electrode being insulated from each other by a planarized thermally grown (PTG) inter-polysilicon oxide (IPO), said gate oxide surrounding said gate electrode and having a less thickness than said field oxide:
said gate oxide and said PTG IPO are thermally grown simultaneously; and
said gate electrode is disposed above said shielded gate electrode.

5. The SGT device of claim 4, wherein a top surface of said shielded gate electrode is lower than a top surface of said adjacent field oxide.

6. The SGT device of claim 4, further comprising a current spreading region of said first conductivity type formed along upper portions of said gate trenches surrounding at least said gate electrode below said body regions, said current spreading region has a doping concentration higher than a doping concentration of said epitaxial layer.

7. The SGT device of claim 4, wherein said epitaxial layer has multiple stepped epitaxial (MSE) layers with different doping concentrations decreasing stepwise in a direction from said substrate to a top surface of said epitaxial layer, wherein each of said MSE layers has an uniform doping concentration as grown.

8. The SGT device of claim 4, wherein said substrate has a first conductivity type, said gate electrode is not electrically shorted together to said source metal, said SGT device is a MOSFET having said gate electrode, said source metal as a source electrode and said back metal as a drain electrode.

9. The SGT device of claim 4, wherein said substrate has a first conductivity type, said gate electrode is electrically shorted together to said source metal; said SGT device is a super barrier rectifier (SBR) having an anode electrode and a cathode electrode, wherein said source metal acts as said anode electrode and said back metal acts as said cathode electrode.

10. The SGT device of claim 4, wherein said substrate has said second conductivity type with a resistivity R; further comprising a buffer layer of said first conductivity type with a resistivity Rb sandwiched between said substrate and said epitaxial layer, said R>said Rb; and said substrate further comprising a plurality of heavily doped regions of said first conductivity type in said substrate to form a plurality of alternating P+ and N+ regions in said substrate.

11. The SGT device of claim 4, further comprising a super junction (SJ) structure comprising a P column region of said second type conductivity disposed on a buffer layer of said first conductivity type with a resistivity Rb sandwiched between said substrate and said epitaxial layer, and said P column region is connected to said body region.

12. The SGT device of claim 11, wherein said substrate has said first conductivity type and said epitaxial layer comprises a single epitaxial layer having an uniform doping concentration with a resistivity R, said R<said Rb.

13. The SGT device of claim 11, wherein said substrate has said second conductivity type and said epitaxial layer comprises a single epitaxial layer having an uniform doping concentration with a resistivity R, said R>said Rb.

14. The SGT device of claim 13, further comprising a plurality of heavily doped regions of said first conductivity type in said substrate to form a plurality of alternating P+ and N+ regions in said substrate.

15. A SGT device formed in an epitaxial layer of a first conductivity type on a substrate of said first conductivity type as a drain region coated with a back metal, further comprising:
a plurality of gate trenches surrounded by source regions of said first conductivity type being encompassed in body regions of a second conductivity type, each of said gate trenches being filled with a gate electrode and a shielded gate electrode; said shielded gate electrode being insulated from said epitaxial layer by a field oxide, said gate electrode being insulated from said epitaxial layer by a gate oxide, said shielded gate electrode and said gate electrode being insulated from each other by a planarized thermally grown (PTG) inter-polysilicon oxide (IPO), said gate oxide surrounding said gate electrode and having a less thickness than said field oxide;
said gate electrode is disposed above said shielded gate electrode; and
a current spreading region of said first conductivity type is formed along upper portions of said gate trenches surrounding at least said gate electrode below said body regions, said current spreading region has a doping concentration higher than a doping concentration of said epitaxial layer;
said epitaxial layer further comprises a source-body (SB) region, an oxide charge balance (OCB) region and a buffer region;
said SB region formed on a top portion of said epitaxial layer;
said OCB region of said first conductivity type formed in a mesa area between two adjacent gate trenches below said body region and above a bottom of said shielded gate electrode;
said buffer region of said first conductivity in said epitaxial layer formed between said substrate and said OCB region; and
said epitaxial layer in said OCB region has multiple stepped epitaxial (MSE) layers with different doping concentrations decreasing stepwise in a direction from a bottom of said shielded gate electrode to a top surface of said epitaxial layer along sidewalls of said gate trenches, wherein each of said MSE layers has an uniform doping concentration as grown.

16. The SGT device of claim 15, wherein said epitaxial layer in said buffer region has a doping concentration lower than doping concentrations of said MSE layers in said OCB region.

17. The SGT device of claim 15, wherein said epitaxial layer in said OCB region comprises at least two stepped epitaxial layers of different doping concentrations including a bottom epitaxial layer with a doping concentration D1 and a top epitaxial layer above said bottom epitaxial layer with a doping concentration D2, wherein said D2<said D1, and said buffer region having a doping concentration DB, wherein said D2<said D1<said DB.

18. The SGT device of claim 15, wherein said epitaxial layer in said OCB region comprises at least two stepped epitaxial layers of different doping concentrations including a bottom epitaxial layer with a doping concentration D1 and a top epitaxial layer above said bottom epitaxial layer with a doping concentration D2, wherein said D2<said D1, and said buffer region having a doping concentration DB, wherein said DB<said D2<said D1.

19. The SGT device of claim 15, wherein said gate electrode is not electrically shorted together to a source metal, said SGT device is a MOSFET having said gate electrode, said source metal as a source electrode and said back metal as a drain electrode.

20. The SGT device of claim 15, wherein said gate electrode is electrically shorted together to a source metal; said SGT device is a super barrier rectifier (SBR) having an anode electrode and a cathode electrode, wherein said source metal acts as said anode electrode and said back metal acts as said cathode electrode.
